(19) United States
(12) Patent Application Publication
(10) Pub. No.: US 2009/0235976 A1
(43) Pub. Date: Sep. 24, 2009

(54) SOLAR CELL

(76) Inventors: Michael Ludowise, San Jose, CA (US); Hing Wah Chan, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 12/050,516

(22) Filed: Mar. 18, 2008

(51) Int. Cl. H01L 31/04; H01L 31/18

(52) U.S. Cl. 136/252; 438/57; 257/E31.002

(57) ABSTRACT

A photovoltaic cell may include a semiconductor base, a semiconductor mesa extending from the semiconductor base, a dielectric and a conductive material. The semiconductor mesa includes a top surface and a side wall, and a first portion of the dielectric is disposed on the top surface, a second portion of the dielectric is disposed on the side wall, and a third portion of the dielectric is disposed on the base. The conductive material is disposed on the top surface of the mesa and on the dielectric, and the conductive material covers the first portion of the dielectric, the second portion of the dielectric, and a portion of the third portion.

### BACKGROUND

1. Field

Some embodiments generally relate to the conversion of solar radiation to electrical energy. More specifically, embodiments may relate to improved photovoltaic cells for use in conjunction with solar collectors.

2. Brief Description

A photovoltaic (or, “solar”) cell generates charge carriers (i.e., holes and electrons) in response to received photons. Many types of solar cells are known, which may differ from one another in terms of constituent materials, structure and/or fabrication methods. A solar cell may be selected for a particular application based on its efficiency, electrical characteristics, physical characteristics and/or cost.

The semiconductor material (e.g., silicon) of a solar cell contributes significantly to total solar cell cost. Accordingly, many approaches have been proposed to increase the output of a solar cell for a given amount of semiconductor material. A concentrating solar radiation collector, for example, may receive solar radiation (i.e., sunlight) over a first surface area and direct the received sunlight to an active area of a solar cell. The active area of the solar cell is several times smaller than the first surface area, yet receives substantially all of the photons received by first surface area. The solar cell may thereby provide an electrical output equivalent to a solar cell having the size of the first surface area.

Other approaches include increasing the size of the active photon-receiving surface area for a given amount of semiconductor material. FIG. 1A is a perspective view and FIG. 1B is a top view of one conventional solar cell. Solar cell 100 includes semiconductor base 110 and semiconductor mesa 120. Semiconductor mesa 120 may include one or more optically-responsive p-n junctions. Each junction may cause generation of charge carriers in response to different photon wavelengths.

Mesa 120 is covered with conductor 130 for collecting current generated by solar cell 100 in response to received photons. Conductor 130 is disposed in a pattern which allows suitable collection of the generated current. Conductor 130 is also disposed over the optically-active area of solar cell 100 and defines field 140 to receive photons into the optically-active area. Field 140 includes the areas within the pattern which are not covered by conductor 130, and is symmetrical about center point 150. Field 140 therefore represents optically-active areas of solar cell 100 which receive photons during operation.

It is desirable to increase a size of a field such as field 140 as a percentage of the total solar cell area. A larger field may allow a solar cell to accept more photons per unit time than a smaller field, leading to increased power generation. A larger field may also increase a tolerance for errors in guiding solar radiation to a desired position on the solar cell. Consequently, increasing a size of an active area as a percentage of the total solar cell area may increase power generation and/or error tolerance for a given amount of semiconductor material, or may allow the maintenance of existing generation and tolerance levels using less semiconductor material.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1A is a perspective view and FIG. 1B is a top view of a solar cell.

FIG. 2 is a top view of a solar cell according to some embodiments.

FIG. 3 is a three-dimensional cutaway view of a portion of the FIG. 2 solar cell according to some embodiments.

FIG. 4 is a cross-sectional view of a contact of the FIG. 2 solar cell according to some embodiments.

FIG. 5 is a top view of a solar cell according to some embodiments.

FIG. 6 is a three-dimensional cutaway view of a portion of the FIG. 5 solar cell according to some embodiments.

FIG. 7 is a cross-sectional view of a first polarity contact of the FIG. 5 solar cell according to some embodiments.

FIG. 8 is a cross-sectional view of a second polarity contact of the FIG. 5 solar cell according to some embodiments.

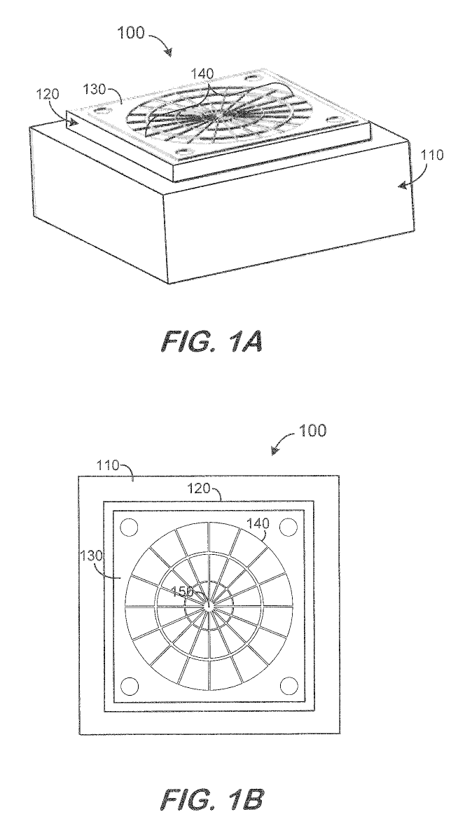

### DETAILED DESCRIPTION

The following description is provided to enable any person in the art to make and use the described embodiments and sets forth the best mode contemplated by for carrying out some embodiments. Various modifications, however, will remain readily apparent to those in the art.

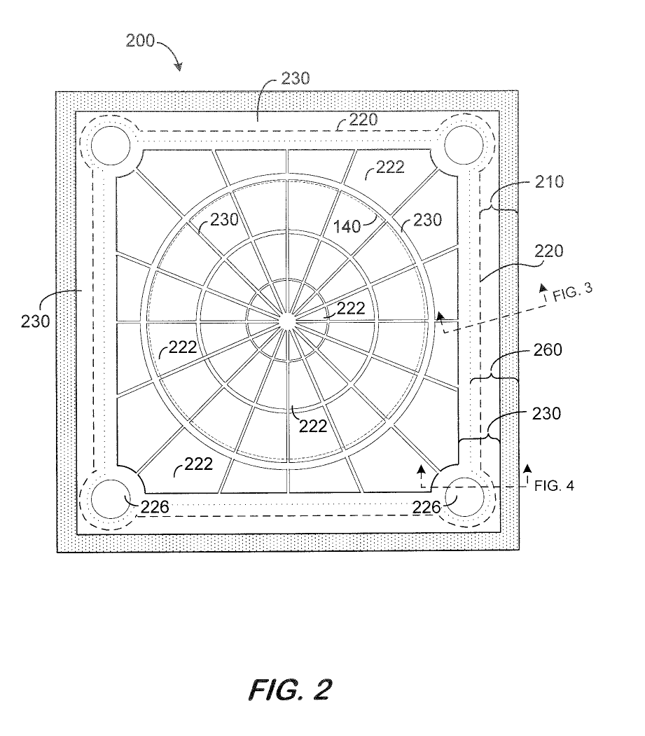

FIG. 2 is a top view of solar cell 200 according to some embodiments. Solar cell 200 may comprise a III-V solar cell, a II-VI solar cell, a silicon solar cell, or any other type of solar cell that is or becomes known. Solar cell 200 may comprise any number of active, dielectric and metallization layers, and may be fabricated using any suitable methods that are or become known.

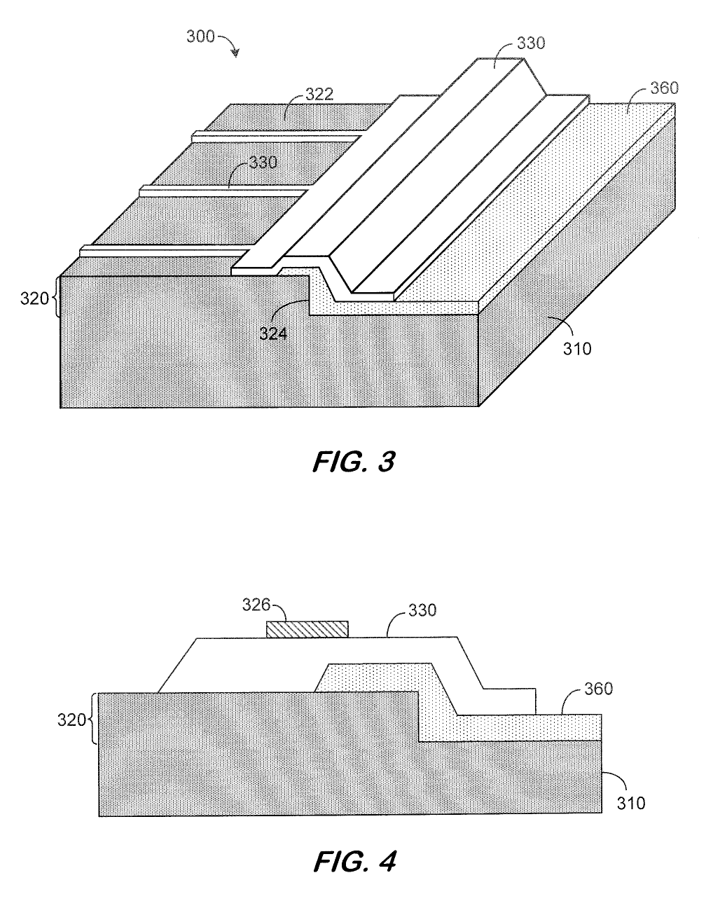

Solar cell 200 comprises semiconductor base 210 and semiconductor mesa 220, an outer edge of which is represented by a dashed line in FIG. 3. Semiconductor mesa 220 and all other semiconductor mesas discussed herein may include one or more p-n junctions deposited using any suitable method. According to some embodiments, the junctions are formed using molecular beam epitaxy and/or metal organic chemical vapor deposition. The junctions may include a Ge junction, a GaAs junction, and a GaInP junction. Each junction exhibits a different band gap energy, which causes each junction to absorb photons of a particular range of energies and generate charge carriers in response thereto.

Conductive material 230 is disposed in a pattern over an optically-active area of top surface 222 of mesa 220. Conductive material 230 may comprise a metal or any suitable conductor. Material 230 is disposed in a pattern over surface 222 to allow suitable collection of the current generated by solar cell 200. Conductive material 230 also defines field 240 to receive photons into the optically-active area of mesa 220. Field 240 is circumscribed by a substantially rectangular (e.g., square) area and includes areas which are not covered by material 230. Field 240 represents optically-active areas of solar cell 200 which receive photons during operation.

Contact material 226 is disposed upon conductive material 230. Contact material 226 may facilitate electrical connections between material 230 and external circuitry. Each of contact material 226 on conductive material 230 may exhibit a same polarity, therefore a lower side of solar cell 200 may comprise contact material (not shown) having an opposite polarity. By virtue of the foregoing arrangement, current may flow between the “top side” and “bottom side” contact material while solar cell 200 generates charge carriers.

Contact material 226 may provide a wettable spot for solder subsequently placed thereon. Contact material 226 may comprise a barrier between such solder and conductive material 230 to prevent intrusion of the solder into material 230 before and after soldering. In some embodiments, a solder mask (not shown) may be deposited on conductive material 230 to further prevent solder from contacting material 230. Contact material 226 may comprise a wirebonding pad in some embodiments.

Conductive material 230 also overlaps the outer edge of mesa 220 and a portion of dielectric 260. As shown, dielectric 260 extends from an inner perimeter represented by a dotted line to an outer edge of base 210. Additional detail and explanation of the arrangement of conductive material 230, dielectric 260 and an outer edge of mesa 220 according to some embodiments will be provided with respect to FIGS. 3 and 4.

In comparison with solar cell 100, the outer perimeter of the photon-receiving field has been moved closer to the mesa edge. Accordingly, the total area of the field as a percentage of semiconductor material has increased. A perimeter of corresponding field 140 according to conventional designs is illustrated as a dashed line for comparative purposes.

In some embodiments, many mesas such as semiconductor mesa 220 are formed on a single semiconductor wafer. For example, p-n junctions may be fabricated on specific areas of the wafer, conductive material may be deposited as shown in FIG. 3 on each area, and semiconductor material between each area may be removed to result in an array of raised mesas on the wafer. The wafer may then be singulated into individual cells as shown in FIG. 2.

FIGS. 3 and 4 are three-dimensional cutaway views to show an arrangement of solar cell 300 according to some embodiments. The cutaway views also depict the respective portions of solar cell 200 indicated in FIG. 2. Accordingly, solar cell 300 may be identical to solar cell 200 of FIG. 2, but embodiments are not limited thereto.

Dielectric 360, which may comprise any suitable dielectric material, is disposed on semiconductor base 310, on side wall 324 of semiconductor mesa 320, and on top surface 322 of mesa 320. Moving from the left to the right of FIG. 3, conductive material 330 is disposed directly on top surface 322 in the field-defining pattern, overlaps dielectric 360 on top surface 322, overlaps dielectric 360 on side wall 324, and overlaps dielectric 360 on a portion of base 310.

Dielectric 360 may prevent shorting of the p-n junctions of mesa 320 by insulating side wall 324 from conductive material 330. Embodiments may therefore allow conductive material 330 to extend past the edge of mesa 320 and to thereby increase the active area of cell 300 expressed as a percentage of the total chip area. By moving conductive material 330 closer to the edge of solar cell 300 and across the edge of mesa 320, otherwise wasted regions of solar cell 300 are utilized more efficiently than in conventional arrangements.

In some embodiments, dielectric 360 and/or conductive material 330 are continuous around a perimeter of semiconductor mesa 320. Embodiments are not limited thereto. In this regard, dielectric 360 may be disposed only at locations where conductive material 330 traverses over the mesa edge to insulate mesa side wall 324 from any such material 330.

The FIG. 4 cross-section is taken across a contact material 326 of mesa top surface 322. FIG. 4 shows dielectric 360 overlapping side wall 324 and conductive material 330 overlapping dielectric 360 as shown in FIG. 3.

The embodiments pictured in FIGS. 2 through 8 each include a frame of conductive material which defines an outer limit of an active area and which is at least partially disposed on top of a semiconductor mesa. In some embodiments, no such frame is disposed on top of the semiconductor mesa. Instead, a dielectric is disposed from above the mesa over a mesa edge and to the chip edge (as shown in FIG. 3) and the conductive grid lines are extended across the mesa edge to a contact ring placed on the dielectric above the semiconductor base. Such an arrangement may further increase the size of the active area as a percentage of semiconductor material.

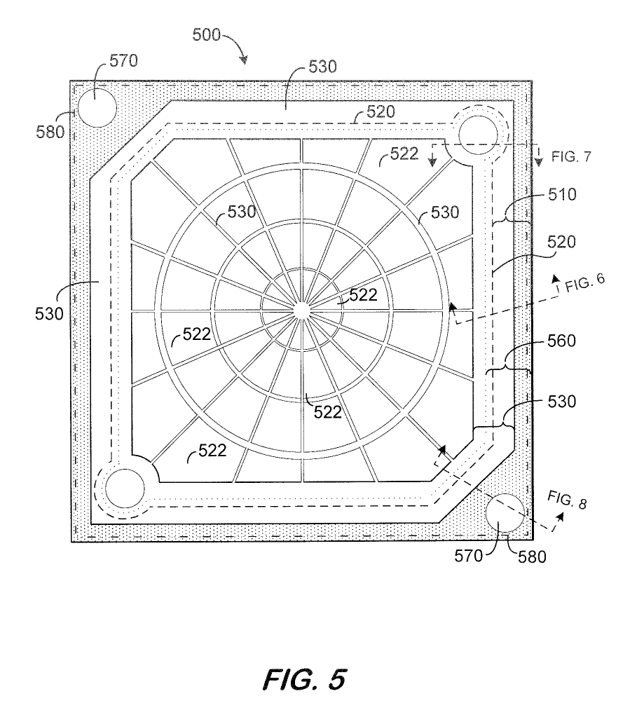

FIG. 5 is a top view of solar cell 500 according to some embodiments. Solar cell 500 provides conductive contacts of opposite polarities on a same side of solar cell 500. Accordingly, a complete electrical circuit may be established via connections to one side of solar cell 500.

Conductive material 530 is disposed in a pattern over an optically-active area of mesa 520. The pattern defines a field to receive photons into the optically-active area. Similar to solar cell 200 of FIG. 2, conductive material 530 overlaps an outer edge (represented by a dashed line) of mesa 520. Dielectric 560 extends from an inner perimeter (represented by a dotted line) to an outer edge of base 510. In some embodiments, dielectric 560 and/or conductive material 530 are continuous around a perimeter of semiconductor mesa 520.

Conductive material 570 is disposed on a top surface of base 510. Conductive material 570 may be used establish a conductive contact having a polarity opposite from a polarity of a contact electrically coupled to material 530 on mesa 520. In some embodiments, base 510 defines lip 580 (represented by a dashed and dotted line) adjacent to conductive material 570. Features of lip 580 will be described below with respect to FIG. 8.

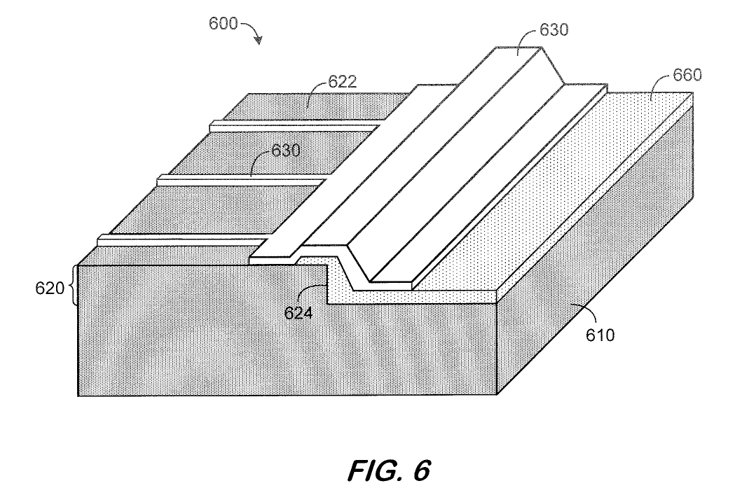

FIGS. 6 through 8 are three-dimensional cutaway views to show an arrangement of solar cell 600 according to some embodiments. The cutaway views also depict the respective portions of solar cell 500 indicated in FIG. 5. Solar cell 600 may be identical to solar cell 500 of FIG. 5, but embodiments are not limited thereto.

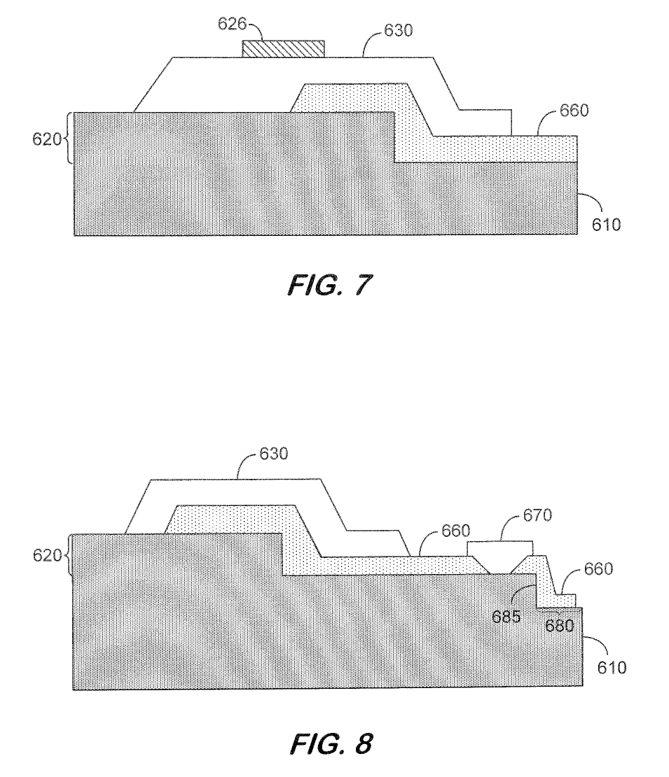

The FIGS. 6 and 7 views are similar to those depicted in FIGS. 3 and 4 with respect to solar cell 300. With reference to FIG. 6, dielectric 660 is disposed on semiconductor base 610, on side wall 624 of semiconductor mesa 620, and on top surface 622 of mesa 620. Conductive material 630 is disposed directly on top surface 622 in the field-defining pattern, overlaps dielectric 660 on top surface 622, overlaps dielectric 660 on side wall 624, and overlaps dielectric 660 on a portion of base 610. As described above, dielectric 660 may prevent shorting of the p-n junctions of mesa 620 by insulating side wall 624 from conductive material 630, and, in some embodiments, may allow conductive material 630 to extend past the edge of mesa 620 and to thereby increase the active area of cell 600 expressed as a percentage of the total chip area.

The FIG. 7 cross-section shows dielectric 660 overlapping side wall 624 and conductive material 630 overlapping dielectric 660. A conductive contact having a first polarity may be coupled to contact material 626.

FIG. 8 is a cross-sectional view of a portion of solar cell 600 including conductive contact 670. Conductive contact 670 may exhibit a polarity opposite from a polarity of a contact electrically coupled to material 630. FIG. 8 illustrates dielectric material 660 and conductive material 630 overlapping an edge of mesa 620 as described above. However, an opening exists in dielectric 660 at the top surface of base 610. Conductive contact 670 is disposed in this opening, thereby establishing electrical contact with base 610.

FIG. 8 also illustrates lip 680 defined by base 610 in some embodiments. Dielectric 680 overlaps side wall 685 of lip 680 to insulate and protect exposed semiconductor material. In the absence of lip 680 and dielectric 660 disposed thereon, conductive contact 670 would be adjacent to an exposed side wall of semiconductor base 610. Accordingly, lip 680 and dielectric 660 disposed thereon allow solar cell 600 to be singulated directly adjacent to conductive contact 670.

Lip 680 may protect mesa 620 against micro-cracks propagating to within the active region during singulation. The likelihood of micro-cracks may be insignificant depending on the materials system and the dimensions chosen for the particular design of cell 600. Since fabrication of lip 680 may add an additional masking layer and a set of related fabrication steps, some embodiments do not include lip 680.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A photovoltaic cell comprising:
a semiconductor base;
a semiconductor mesa extending from the semiconductor base, the semiconductor mesa comprising a top surface and a side wall;
a dielectric, a first portion of the dielectric disposed on the top surface, a second portion of the dielectric disposed on the side wall, and a third portion of the dielectric disposed on the base; and
conductive material disposed on the top surface of the mesa and on the dielectric,
wherein the conductive material covers the first portion of the dielectric, the second portion of the dielectric, and a portion of the third portion.

2. A photovoltaic cell according to claim 1, wherein the semiconductor mesa comprises an optically-active semiconductor area, and
wherein the conductive material is disposed in a pattern over the optically-active semiconductor area, the pattern defining a field to receive photons into the optically-active semiconductor area.

3. A photovoltaic cell according to claim 1, wherein the dielectric is continuous around a perimeter of the semiconductor mesa.

4. A photovoltaic cell according to claim 3, wherein the conductive material is continuous around the perimeter of the semiconductor mesa.

5. A photovoltaic cell according to claim 1, wherein the conductive material exhibits a first polarity, the cell further comprising:
a conductive contact in contact with a top surface of the mesa,
wherein the conductive contact exhibits a second polarity.

6. A photovoltaic cell according to claim 5, wherein the semiconductor defines a lip adjacent to the conductive contact, and
wherein the dielectric overlaps a side wall of the lip.

7. A photovoltaic cell according to claim 5, wherein the semiconductor mesa comprises an optically-active semiconductor area,
wherein the conductive material is disposed in a pattern over the optically-active semiconductor area, the pattern defining a field to receive photons into the optically-active semiconductor area, and
wherein the field is asymmetric about a center point of the optically-active semiconductor area.

8. A method comprising:
fabricating a semiconductor base and a semiconductor mesa extending from the semiconductor base, the semiconductor mesa comprising an optically-active semiconductor area, a top surface and a side wall;
depositing a dielectric, a first portion of the dielectric deposited on the top surface, a second portion of the dielectric deposited on the side wall, and a third portion of the dielectric deposited on the base; and
depositing conductive material on the top surface of the mesa and on the dielectric,
wherein the conductive material covers the first portion of the dielectric, the second portion of the dielectric, and a portion of the third portion.

9. A method according to claim 8, wherein the conductive material is disposed in a pattern over the optically-active semiconductor area, the pattern defining a field to receive photons into the optically-active semiconductor area, and
wherein the field is asymmetric about a center point of the optically-active semiconductor area.

10. A method according to claim 8, wherein the dielectric is continuous around a perimeter of the semiconductor mesa.

11. A method according to claim 10, wherein the conductive material is continuous around the perimeter of the semiconductor mesa.

12. A method according to claim 8, further comprising:
fabricating a conductive contact in contact with a top surface of the base,
wherein the conductive contact exhibits a polarity opposite from a polarity of the conductive material.

13. A method according to claim 12, wherein fabricating the semiconductor base comprises fabricating a lip at an outer edge of the semiconductor base and adjacent to a location of the conductive contact, and
wherein the dielectric overlaps a side wall of the lip.
